(19) United States
(12) Patent Application Publication
(10) Pub. No.: US 2015/0144990 A1
(43) Pub. Date: May 28, 2015

(54) POWER SEMICONDUCTOR DEVICE AND METHOD OF MANUFACTURING THE SAME

(71) Applicant: SAMSUNG ELECTRO-MECHANICS CO., LTD., Suwon-Si (KR)

(72) Inventors: Jae Hoon PARK, Suwon-Si (KR); In Hyuk SONG, Suwon-Si (KR); Dong Soo SEO, Suwon-Si (KR); Ji Yeon OH, Suwon-Si (KR); Kee Ju UM, Suwon-Si (KR)

(73) Assignee: SAMSUNG ELECTRO-MECHANICS CO., LTD., Suwon-Si (KR)

(21) Appl. No.: 14/273,378

(22) Filed: May 8, 2014

(30) Foreign Application Priority Data
Nov. 27, 2013 (KR) 10-2013-0145004

(51) Int. Cl. H01L 29/423; H01L 29/73; H01L 21/28; H01L 29/66

(52) U.S. Cl. CPC H01L 29/42312; H01L 29/66325; H01L 29/73; H01L 29/4236; H01L 21/28
USPC 257/139; 438/133

(57) ABSTRACT

A power semiconductor device may include a first semiconductor region having a first conductivity type, a second semiconductor region having a second conductivity type formed on an upper portion of the first semiconductor region, a third semiconductor region having a first conductivity type formed in an inner portion of an upper portion of the second semiconductor region, a trench gate formed to penetrate from the third semiconductor region to the first semiconductor region and including a first insulating layer formed on a surface thereof, and a second insulating layer formed in a lower portion of the trench gate.

### CROSS-REFERENCE TO RELATED APPLICATION

This application claims the benefit of Korean Patent Application No. 10-2013-0145004 filed on Nov. 27, 2013, with the Korean Intellectual Property Office, the disclosure of which is incorporated herein by reference.

### BACKGROUND

The present disclosure relates to a power semiconductor device including a trench gate and a method of manufacturing the same.

An insulated gate bipolar transistor (IGBT) is a transistor manufactured to have bipolarity by forming a gate using a metal oxide semiconductor (MOS) and forming a p-type collector layer on a rear surface thereof.

After the development of power metal oxide semiconductor field effect transistors (MOSFET) according to the related art, such transistors have been used in fields requiring high speed switching characteristics.

However, due to structural limitations of MOSFETs, bipolar transistors, thyristors, gate turn-off thyristors (GTO), and the like, have been used in fields in which high voltages are present.

Since IGBTs have characteristics such as a low forward loss and rapid switching speeds, the application of IGBTs to fields to which existing thyristor, bipolar transistor, MOSFET, and the like, may not be practically applied, has increased.

In the case in which a power semiconductor device such as a MOSFET or an IGBT has a trench gate, in order to form a channel, the trench gate is formed to be in contact with a p-type body region.

Particularly, in the case in which the trench gate does not have a depth sufficient to form the channel having a shape penetrating through the body region, performance and reliability of the power semiconductor device is rapidly decreased.

However, in the case in which the trench gate has a depth deeper than that of the body region, parasitic capacitance (Cgc) may be formed between the trench gate and a collector or a drain, thereby causing degradations in switching performance of the power semiconductor device.

In the case of a power semiconductor device according to the related art, in order to decrease parasitic capacitance, a gate insulating layer formed on the trench gate is formed using SiO₂ and is relatively thick.

However, in the case in which the gate insulating layer is relatively thick, a precipitation phenomenon of boron is intensified, such that Vth may be changed.

The following related art document discloses an example in which an insulating layer of a lower portion of the trench gate has a thick thickness.

### RELATED ART DOCUMENT

U.S. Pat. No. 6,882,000

### SUMMARY

Some embodiments of the present disclosure may provide a power semiconductor device having a structure capable of decreasing parasitic capacitance and a method of manufacturing the same.

According to some embodiments of the present disclosure, a power semiconductor device may include: a first semiconductor region having a first conductivity type; a second semiconductor region having a second conductivity type formed on an upper portion of the first semiconductor region; a third semiconductor region having a first conductivity type formed in an inner portion of an upper portion of the second semiconductor region; a trench gate formed to penetrate from the third semiconductor region to the first semiconductor region and including a first insulating layer formed on a surface thereof; and a second insulating layer formed in a lower portion of the trench gate and having a dielectric constant lower than that of the first insulating layer.

The power semiconductor device may further include a fourth semiconductor region having a first conductivity type formed between the first semiconductor region and the second semiconductor region and having an impurity concentration higher than that of the first semiconductor region.

The second insulating layer may be formed from the lower portion of the trench gate to a height at which the second semiconductor region and the fourth semiconductor region are in contact.

A material of the second insulating layer may be formed using SiN.

When capacitance of the first insulating layer is C1 and capacitance of the second insulating layer is C2, the trench gate may have parasitic capacitance satisfying (C1×C2)/(C1+C2).

The power semiconductor device may further include a conductive material filling the trench gate, and a depth to which the conductive material is formed may be equal to a depth of the second semiconductor region.

According to some embodiments of the present disclosure, a method of manufacturing a power semiconductor device may include: preparing a first semiconductor region having a first conductivity type; preparing a trench gate by etching an upper surface of the first semiconductor region, forming a first insulating layer, and then forming a second insulating layer having a dielectric constant lower than that of the first insulating layer, in a lower portion of the trench gate; forming a second semiconductor region having a second conductivity type by implanting second conductivity type impurities into an upper portion of the first semiconductor region; and forming a third semiconductor region having a first conductivity type by implanting first conductivity type impurities into an upper portion of the second semiconductor region.

The etching of the upper surface of the first semiconductor region in the preparing of the trench gate may include: forming a preliminary trench by etching the first semiconductor region; forming a fourth semiconductor region by implanting the first conductivity type impurities into the etched portion; and etching the preliminary trench.

The second insulating layer may be formed from the lower portion of the trench gate to a height at which the second semiconductor region and the fourth semiconductor region are in contact.

The second insulating layer may be formed using SiN.

When capacitance of the first insulating layer is C1 and capacitance of the second insulating layer is C2, the trench gate may have parasitic capacitance satisfying (C1×C2)/(C1+C2).

The method may further include filling the trench gate with a conductive material, and a depth to which the conductive material is formed may be equal to a depth in which the second semiconductor region is formed from the upper surface of the second semiconductor region.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 illustrates a schematic cross-sectional view of a power semiconductor device according to an exemplary embodiment of the present disclosure;

FIG. 2 illustrates a schematic cross-sectional view of a power semiconductor device including a hole accumulation region according to an exemplary embodiment of the present disclosure; and

FIG. 3 is a flowchart schematically illustrating a method of manufacturing a power semiconductor device according to another exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

A power switch may be implemented by any one of a power metal oxide semiconductor field effect transistor (MOSFET), an insulated gate bipolar transistor (IGBT), several types of thyristor, and devices similar to the above-mentioned devices. Most of new technologies disclosed herein will be described based on the IGBT. However, several exemplary embodiments of the present disclosure disclosed herein are not limited to the IGBT, but may also be applied to other types of power switch technology including a power MOSFET and several types of thyristor in addition to the IGBT. Further, several exemplary embodiments of the present disclosure will be described as including specific p-type and n-type regions. However, conductivity types of several regions disclosed herein may be similarly applied to devices having conductivity types opposite thereto.

In addition, an n-type or a p-type used herein may be defined as a first conductivity type or a second conductivity type. Meanwhile, the first and second conductivity types indicate different conductivity types.

Further, generally, positive ‘+’ is a state in which a region is heavily doped and negative ‘−’ is a state in which a region is lightly doped.

Hereinafter, although the case in which the first conductivity type is the n-type and the second conductivity type is the p-type will be described in order to make a description clear, the present disclosure is not limited thereto.

In addition, a first semiconductor region represents adrift region, a second semiconductor region represents a body region, and a third semiconductor region represents an emitter region, but they are not limited thereto.

In addition, a fourth semiconductor region represents a hole accumulation region, but is not limited thereto.

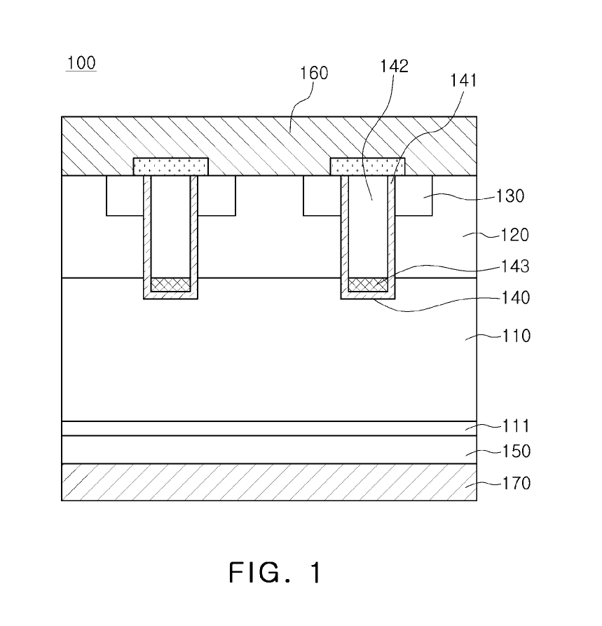

FIG. 1 illustrates a schematic cross-sectional view of a power semiconductor device 100 according to an exemplary embodiment of the present disclosure.

The power semiconductor device 100 according to an exemplary embodiment of the present disclosure may include a drift region 110, a body region 120, an emitter region 130, and a collector region 150.

The drift region 110 may be formed by implanting n-type impurities at a relatively low concentration.

Therefore, the drift region 110 may have a relatively thick thickness in order to maintain a withstand voltage of the power semiconductor device.

The drift region 110 may further include a buffer region 111 formed therebelow.

The buffer region 111 may be formed by implanting n-type impurities into a rear surface of the drift region 110.

The buffer region 111 may serve to block extension of a depletion region of the power semiconductor device at the time of the extension of the depletion region, thereby assisting in maintaining a withstand voltage of the power semiconductor device.

Therefore, in the case in which the buffer region 111 is formed, a thickness of the drift region 110 may be decreased, such that the power semiconductor device may be miniaturized.

The drift region 110 may have the body region 120 formed on an upper part thereof by implanting p-type impurities.

The body region 120 may be lengthily formed in one direction when being viewed from a top of the power semiconductor device.

For example, the body region 120 may be formed in a stripe shape.

The body region 120 may have a conductivity type corresponding to a p-type to form a p-n junction with the drift region 110.

The body region 120 may have the emitter region 130 formed in an inner portion of an upper portion thereof by implanting n-type impurities at a relatively high concentration.

The emitter region 130 may be distributed in the body region 120 to be formed in a plurality of regions.

A trench gate 140 may be formed from an upper surface of the emitter region 130 to a portion of the drift region 110 through the body region 120.

For example, the trench gate 140 may penetrate from the emitter region 130 into a portion of the drift region 110.

The trench gate 140 may include a first insulating layer 141 formed in a portion thereof contacting the drift region 110, the body region 120, and the emitter region 130.

The first insulating layer 141 may be formed using a silicon oxide (SiO₂), but is not limited thereto.

The trench gate 140 may include a conductive material 142 filled therein.

The conductive material 142 may be a polysilicon (poly-Si) or a metal, but is not limited thereto.

The conductive material 142 may be electrically connected to a gate electrode (not shown) to control an operation of the power semiconductor device according to an exemplary embodiment of the present disclosure.

In the case in which a positive voltage is applied to the conductive material 142, a channel may be formed in the body region 120.

In detail, in the case in which the positive voltage is applied to the conductive material 142, electrons present in the body region 120 may be drawn toward the trench gate 140 and be collected in the trench gate 140, such that the channel may be formed.

For example, electrons and holes may be recombined with each other due to a p-n junction, such that the trench gate 140 in a depletion region in which carriers are not present pulls the electrons to form the channel, whereby a current may flow.

The drift region 110 or the buffer region 111 may include the collector region 150 formed therebelow by implanting p-type impurities.

In the case in which the power semiconductor device is the IGBT, the collector region 150 may provide holes to the power semiconductor device.

Due to injection of the holes, minority carriers, at a high concentration, a conductivity modulation that conductivity in the drift region is increased several ten or several hundred times occurs.

A resistance component in the drift region 110 becomes very small due to the conductivity modulation. Therefore, the IGBT may be used at a very high voltage.

In a case of the power semiconductor device 100 having the trench gate according to an exemplary embodiment of the present disclosure, the trench gate 140 may be formed to penetrate through the body region 120 in order to operate the power semiconductor device.

The trench gate 140 which is extended to the drift region 110 based on the body region 120 becomes a main cause of an increase in parasitic capacitance Cgc between the gate and the collector.

For example, in the case in which the trench gate 140 is extended to the drift region 110, when the positive voltage is applied to the conductive material 142 formed in the trench gate 140, the electrons in the drift region 110 as well as the body region 120 are drawn toward the trench gate 140.

Therefore, the electrons which are drawn toward the portion in which the drift region 110 and the trench gate 140 contact affect the conductive material 142, such that the voltage applied to the trench gate 140 is fluctuated.

In the case in which the voltage applied to the trench gate 140 is fluctuated, noise may be generated from the power semiconductor device 100, thereby decreasing reliability of the power semiconductor device.

In order to decrease the parasitic capacitance, the power semiconductor device 100 according to an exemplary embodiment of the present disclosure may include a second insulating layer 143 formed in a lower portion of the trench gate 140.

For example, the second insulating layer 143 may be formed from the lower portion of the trench gate 140 to a height at which the body region 120 and the drift region 110 contact.

For example, the second insulating layer 143 may be formed from the lower portion of the trench gate 140 to a horizontal surface at which the body region 120 and the drift region 110 contact.

In the case in which the second insulating layer 143 is formed in the lower portion of the trench gate 140, the parasitic capacitance of the lower portion of the trench gate 140 extended to the drift region 110 may be decreased.

For example, in the case in which the second insulating layer 143 is formed in the lower portion of the trench gate 140, the first insulating layer 141 and the low-dielectric insulating layer 143 may have a configuration in which they are connected in series, such as a capacitor.

When capacitance of the first insulating layer 141 is C1 and capacitance of the second insulating layer 143 is C2, the parasitic capacitance Cgc of the trench gate 140 may satisfy a relationship of (C1×C2)/(C1+C2).

Therefore, the power semiconductor device may have the parasitic capacitance lower than the case in which only the first insulating layer 141 is formed therein.

Since the power semiconductor device 100 according to an exemplary embodiment of the present disclosure has the second insulating layer 143 formed in the lower portion of the trench gate 140, the parasitic capacitance may be significantly reduced. Therefore, the occurrence of noise which may be caused upon switching-on the power semiconductor device according to an exemplary embodiment of the present disclosure may be decreased and switching loss may be decreased.

The second insulating layer 143 may be formed using SiN, but is not limited thereto.

For example, in the case in which the first insulating layer 141 is formed using SiO₂, the second insulating layer 143 may be formed using a material having a dielectric constant lower than that of SiO₂.

In order to further decrease the parasitic capacitance, the conductive material 142 may have the same depth as the body region 120.

For example, the conductive material 142 may be formed so that a level of the lowest termination in a height direction is equal to a level of a horizontal surface at which the drift region 110 and the body region 120 contact.

Since the conductive material 142 has the same depth as the body region 120, a channel may be formed in the portion at which the body region 120 and the trench gate 140 contact when the power semiconductor device is turned-on.

At the same time, since the conductive material 142 is not formed at the height corresponding to the portion at which the drift region 110 and the trench gate 140 contact, the parasitic capacitance of the trench gate 142 may be significantly decreased.

In the case in which the power semiconductor device is the MOSFET, the collector region 150 may have an n-type conductivity.

The emitter region 130 and the body region 120 may have an emitter metal layer 160 formed on exposed upper surfaces thereof, and the collector region 150 may have a collector metal layer 170 formed on a lower surface thereof.

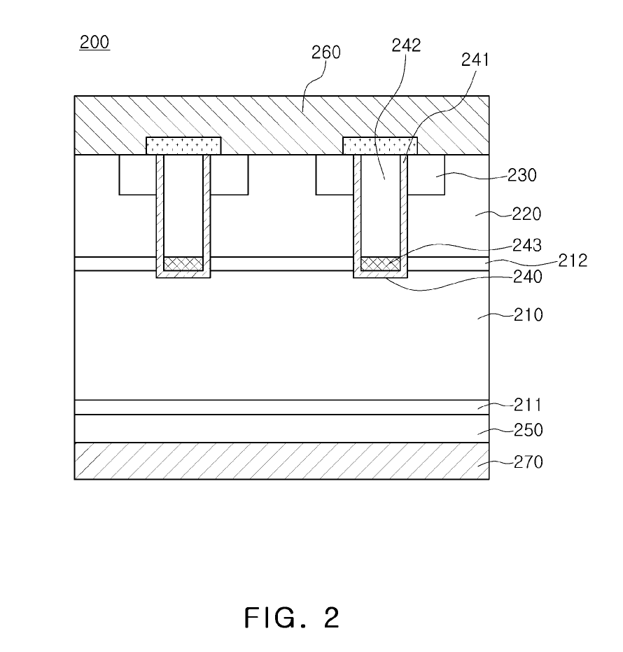

FIG. 2 illustrates a schematic cross-sectional view of a power semiconductor device 200 including a hole accumulation region 212 according to an exemplary embodiment of the present disclosure.

The power semiconductor device 200 according to an exemplary embodiment of the present disclosure may include the hole accumulation region 212 formed between the drift region 210 and the body region 220 and having an n-type impurity concentration higher than that of the drift region 210.

The hole accumulation region 212 significantly increases an accumulated amount of holes to significantly increase conductivity modulation, whereby the loss when the power semiconductor device is turned on may be decreased.

In order to decrease parasitic capacitance, a second insulating layer 243 may be formed in a lower portion of a trench gate 240.

The second insulating layer 243 may be formed from the lower portion of the trench gate 240 to a height at which the body region and the hole accumulation region 212 contact.

In the case in which the hole accumulation region 212 is formed, the holes collected in the hole accumulation region 212 may affect an input signal of the trench gate 240.

For example, the trench gate 240 is affected by the hole accumulation region 212, whereby gate noise may be generated.

The gate noise fluctuates a stable supply of a current and in the case in which a switching frequency is relatively high, a variation width of the current is significantly increased due to the gate noise.

Therefore, the second insulating layer 243 is formed from the lower portion of the trench gate 240 to the height at which the body region and the hole accumulation region 212 contact, whereby the conductivity modulation effects due to the hole accumulation region 212 may be significantly increased and the parasitic capacitance may be significantly decreased to thereby significantly decrease noise.

A description of the same components of the power semiconductor device 200 shown in FIG. 2 as those of the power semiconductor device 100 shown in FIG. 1 will be omitted.

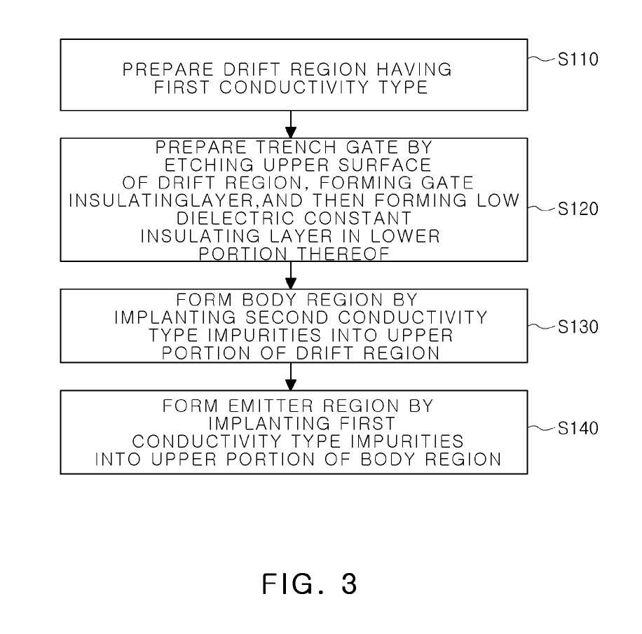

FIG. 3 is a flow chart schematically illustrating a method of manufacturing a power semiconductor device according to another exemplary embodiment of the present disclosure.

A method of manufacturing a power semiconductor device according to another exemplary embodiment of the present disclosure will be described with reference to FIG. 3. The method of manufacturing the power semiconductor device according to another exemplary embodiment of the present disclosure may include an operation of preparing a conductivity type drift region having an n-type (S110); an operation of preparing a trench gate by etching an upper surface of the drift region, forming a first insulating layer, and then forming a second insulating layer in a lower portion thereof (S120); an operation of forming a body region by implanting p-type impurities into an upper portion of the drift region (S130); and an operation of forming an emitter region by implanting n-type impurities into an upper portion of the body region (S140).

First, the preparing of the conductivity type drift region having the n-type (S110) may be performed.

The preparing of the drift region (S110) may be performed using an epitaxial method and may be performed to have a relatively low n-type impurity concentration.

After the drift region is formed, the forming of the trench gate (S120) thereon may be performed.

The forming of the trench gate (S120) may be performed to include etching an upper portion of the drift region, forming a first insulating layer on a surface, forming a second insulating layer in a lower portion of the trench gate having the first insulating layer formed thereon, and filling an inner portion of the trench gate with a conductive material.

In order to significantly decrease parasitic capacitance, the second insulating layer may be formed from the lower portion of the trench gate to a height at which the emitter region 230 and the drift region are in contact.

In addition, in order to significantly decrease the parasitic capacitance, a depth to which the conductive material is formed may be the same as the depth of the emitter region.

In the case in which the second insulating layer 143 is formed in the lower portion of the trench gate 140, the parasitic capacitance of the lower portion of the trench gate 140 extended to the drift region 110 may be decreased.

For example, in the case in which the second insulating layer 143 is formed in the lower portion of the trench gate 140, the first insulating layer 141 and the low-dielectric insulating layer 143 may have a configuration of a serial connection such as a capacitor.

When capacitance of the first insulating layer is C1 and capacitance of the second insulating layer 143 is C2, the parasitic capacitance Cgc of the trench gate may satisfy a relationship of (C1×C2)/(C1+C2).

Therefore, the power semiconductor device may have parasitic capacitance lower than the case in which only the first insulating layer is formed therein.

After the forming of the trench gate (S120) is performed, an operation of forming a body region by implanting p-type impurities into the upper portion of the drift region (S130) may be performed.

Next, an operation of forming an emitter region by implanting n-type impurities into an upper portion of the body region (S140) may be performed.

The forming of the emitter region (S40) may performed by forming a mask on the upper portion of the body region and by implanting the n-type impurities into a portion in which the mask is not formed.

After the forming of the emitter region (S140) is performed, an emitter electrode may be formed on a surface thereof on which the emitter region is formed.

After the emitter electrode is formed, a thickness of the drift region may be adjusted by removing a portion of the drift region positioned at the lower portion thereof by a grinding method, or the like.

Next, a buffer layer may be formed by implanting the n-type impurities into a lower surface, as necessary.

In the case of the IGBT, the collector region may be formed by implanting the p-type impurities into a lower portion of the drift region or a lower portion of the buffer region and a collector metal layer may then be formed below the collector region.

In the case of the MOSFET, the collector metal layer may be formed at the lower portion of the drift region or the buffer layer without implanting the p-type impurities into the lower portion of the drift region or the buffer layer.

In order to form a hole accumulation region, the etching of the upper surface of the drift region in the operation of preparing the trench gate (S120) may include forming a preliminary trench by etching the drift region; forming a hole accumulation region by implanting n-type impurities into the etched portion; and etching the preliminary trench.

The n-type impurities implanted into the hole accumulation region may have the concentration higher than that of the drift region.

Since the concentration of the n-type impurities in the hole accumulation region is relatively high, the holes are accumulated in the lower portion of the hole accumulation region upon switching-on the power semiconductor device, whereby the conductivity modulation may be significantly increased.

By performing a heat processing after the n-type impurities are implanted, the n-type impurities are diffused, whereby the hole accumulation region may be formed.

In addition, the n-type impurities are diffused by performing the heat processing, whereby the hole accumulation region may be formed on a portion at which the body region and the drift region are in contact.

In order to decrease the loss at the time at which the power semiconductor device is switched on and to significantly decrease parasitic capacitance, the second insulating layer may be formed from the lower portion of the trench gate to the height at which the body region and the hole accumulation region are in contact.

The exemplary embodiments of the present disclosure may be performed through a combination with one another.

For example, the above-described n-type conductivity and p-type conductivity may also be changed during implementation.

According to exemplary embodiments of the present disclosure, the power semiconductor device may decrease the parasitic capacitance by including the low-dielectric insulating layer formed in the lower portion of the trench gate.

As the parasitic capacitance is decreased, the occurrence of the noise which may be caused upon switching-on the power semiconductor device according to an exemplary embodiment of the present disclosure may be decreased and the switching loss may be decreased.

The power semiconductor device according to another exemplary embodiment of the present disclosure includes the hole accumulation region to generate the conductivity modulation, whereby the loss at the time in which the power semiconductor device is switched on may be decreased.

In addition, the power semiconductor device may decrease the parasitic capacitance caused by the hole accumulation region by including the low-dielectric insulating layer which is formed from the lower portion of the trench gate to the height at which the body region and the hole accumulation region are in contact.

As the parasitic capacitance is decreased, the occurrence of the noise which may be caused upon switching-on the power semiconductor device according to another exemplary embodiment of the present disclosure may be decreased and the switching loss may be decreased.

While exemplary embodiments have been shown and described above, it will be apparent to those skilled in the art that modifications and variations could be made without departing from the spirit and scope of the present disclosure as defined by the appended claims.

What is claimed is:

1. A power semiconductor device, comprising:
a first semiconductor region of first conductivity type;
a second semiconductor region of second conductivity type disposed on an upper portion of the first semiconductor region;
a third semiconductor region of the first conductivity type disposed in an inner portion of an upper portion of the second semiconductor region;
a trench gate penetrating from the third semiconductor region to the first semiconductor region and including a first insulating layer disposed on a surface of the trench gate; and
a second insulating layer disposed in a lower portion of the trench gate and having a dielectric constant lower than that of the first insulating layer.

2. The power semiconductor device of claim 1, further comprising a fourth semiconductor region having a first conductivity type formed between the first semiconductor region and the second semiconductor region and having an impurity concentration higher than that of the first semiconductor region.

3. The power semiconductor device of claim 2, wherein the second insulating layer is formed from the lower portion of the trench gate to a height at which the second semiconductor region and the fourth semiconductor region are in contact.

4. The power semiconductor device of claim 1, wherein the second insulating layer is formed using SiN.

5. The power semiconductor device of claim 1, wherein when capacitance of the first insulating layer is C1 and capacitance of the second insulating layer is C2, the trench gate has parasitic capacitance satisfying (C1×C2)/(C1+C2).

6. The power semiconductor device of claim 1, further comprising a conductive material filling the trench gate, wherein a depth to which the conductive material is formed is equal to a depth of the second semiconductor region.

7. A method of manufacturing a power semiconductor device, the method comprising:
preparing a first semiconductor region having a first conductivity type;
preparing a trench gate by etching an upper surface of the first semiconductor region, forming a first insulating layer, and then forming a second insulating layer having a dielectric constant lower than that of the first insulating layer, in a lower portion of the trench gate;
forming a second semiconductor region having a second conductivity type by implanting second conductivity type impurities into an upper portion of the first semiconductor region; and
forming a third semiconductor region having a first conductivity type by implanting first conductivity type impurities into an upper portion of the second semiconductor region.

8. The method of claim 7, wherein the etching of the upper surface of the first semiconductor region in the preparing of the trench gate comprises:
forming a preliminary trench by etching the first semiconductor region;
forming a fourth semiconductor region by implanting the first conductivity type impurities into the etched portion; and
etching the preliminary trench.

9. The method of claim 8, wherein the second insulating layer is formed from the lower portion of the trench gate to a height at which the second semiconductor region and the fourth semiconductor region are in contact.

10. The method of claim 7, wherein the second insulating layer is formed using SiN.

11. The method of claim 7, wherein when capacitance of the first insulating layer is C1 and capacitance of the second insulating layer is C2, the trench gate has parasitic capacitance satisfying (C1×C2)/(C1+C2).

12. The method of claim 7, further comprising filling the trench gate with a conductive material,
wherein a depth to which the conductive material is formed is equal to a depth in which the second semiconductor region is formed from the upper surface of the second semiconductor region.
